(19) United States
(12) Patent Application Publication
(10) Pub. No.: US 2008/0202804 A1
(43) Pub. Date: Aug. 28, 2008

(54) PRINTED CIRCUIT BOARD AND METHOD OF PRODUCING THE SAME

(76) Inventors: YASUHIRO FAKUTOMI, Tokyo (JP); Yuuji Minota, Tokyo (JP); Motonobu Koike, Yamanashi (JP)

Correspondence Address: NEC CORPORATION OF AMERICA, 6535 N. STATE HWY 161, IRVING, TX, 75039, US

(21) Appl. No.: 12/033,318

(22) Filed: Feb. 19, 2008

(30) Foreign Application Priority Data
Feb. 26, 2007 (JP) 2007-046262

(51) Int. Cl. H05K 1/00; B23K 1/20

(52) U.S. Cl. 174/267; 228/203

(57) ABSTRACT

There is provided a printed circuit board in which space between pads used for surface mounting can be narrowed and an FPC can be mounted along with electronic components by the reflow method even when the FPC is mounted and a method of producing the same. A printed circuit board is configured such that a solder resist 3 is formed on the surface of the printed circuit board so as to expose pads 2, a solder resist 4 is formed between the adjacent pads, and solder paste which is as high as or higher than the solder resist 4 is provided by printing on the pad 2 separated from other pads 2 by the solder resists 3 and 4.

This application is based upon and claims the benefit of priority from Japanese patent application No. 2007-046262, filed on Feb. 26, 2007, the disclosure of which is incorporated herein in its entirety by reference.

### BACKGROUND OF THE INVENTION

The present invention relates to a printed circuit board provided with pads used for surface mounting and a method of producing the same, and in particular, to a printed circuit board that prevents molten solder from flowing into other adjacent pads and a method of producing the same.

### DESCRIPTION OF RELATED ART

Most of the apparatuses such as communication apparatuses have been downsized and compacted in recent years. This tendency also requires built-in devices to be downsized and compacted, so that a circuit board assembled inside needs to be further downsized and many components need to be mounted.

When electronic components are surface-mounted on a printed circuit board (PCB), the following method (reflow method) is generally used. In this case, solder paste is applied beforehand over a predetermined place of the PCB and then electronic components are placed on the paste and heated. After the solder has melted, it is solidified again.

When electronic components are mounted by the reflow method, a narrow space between pads (or narrow pitch) causes molten solder to flow into adjacent pads to produce a defect such as formation of a solder bridge.

The PCB is often connected to other PCBs or electronic components through a flexible printed circuit board (FPC) to increase its functions.

There exist the following four configurations for connecting the FPC to the PCB: the FPC is connected to the PCB through an FPC connector; the FPC and the PCB are integrated together into a flex-rigid printed wiring board; the FPC is soldered to the PCB by using a solder iron; and the FPC is connected to the PCB by using an anisotropic conductive film (ACF).

In the above four configurations, the configuration in which the FPC connector is used has a disadvantage that the number of components is increased, which makes it difficult to meet the requirement for downsizing and compacting an electronic apparatus demanded in recent years.

The flex-rigid printed wiring board is more expensive than the PCB or the FPC alone, which results in a disadvantage in cost and delivery.

The configuration in which the FPC is soldered to the PCB has an advantage in cost, but has a disadvantage that dedicated facilities are required. Difficulty in narrowing a pitch makes it further difficult to meet the requirement for downsizing and compacting a product.

The above configuration in which the FPC is connected to the PCB by using the ACF requires dedicated facilities and makes it difficult to increase a connecting strength.

As a related art concerned with surface mounting on the PCB, there exist “Print Circuit Board and Method of Producing the Same” disclosed in Patent Document 1. The invention disclosed in the Patent Document 1 is such that an n-layered solder resist is provided at the time of mounting semiconductor elements to maintain the height of a solder bump to increase a heat-proof cycle property.

[Patent Document 1] Japanese Patent Application No. 2006-202881

The invention disclosed in the Patent Document 1 aims at surface mounting of semiconductor elements and uses the solder bump used for surface mounting on the PCB. However, when electronic components as well as the FPC are surface-mounted on the PCB using the solder bump, the electronic components and the FPC cannot be mounted on the PCB at the same process, so that these need to be mounted on the PCB at separate processes.

Furthermore, when the electronic components to be mounted on the PCB include a component of which pads are provided at the inside of the other side thereof (for example, a quad flat no-lead (QFN) package) and also a component of which pads are provided around the end face thereof, the solder bumps need to be formed at separate processes, further increasing man-hour for production.

Still furthermore, a connection using the solder bump needs to fill underfill resin to reinforce a connection portion because the electronic components are fixed on the float above the surface of the solder resist, which also increases man-hour for production.

Thus, hitherto, it has not been realized that space between pads used for surface mounting can be narrowed and an FPC can be structurally mounted along with electronic components by the reflow method even when the FPC is mounted.

The present invention has been made in view of the problems. An exemplary object of the present invention is to provide a printed circuit board in which space between pads used for surface mounting can be narrowed and an FPC can be mounted along with electronic components by the reflow method even when the FPC is mounted and a method of producing the same.

### SUMMARY OF THE INVENTION

To achieve the above object, the first aspect of the present invention provides a printed circuit board provided with a mounting section including a plurality of pads used for surface mounting, wherein a first solder resist is formed on the surface of the printed circuit board so as to expose the pads, a second solder resist is formed between the adjacent pads, and a printing layer of solder paste which is as high as or higher than the second solder resist is provided on the pad separated from other pads by the first and the second solder resists.

In the first aspect of the present invention, the pad is preferably used for mounting a flexible printed circuit board. Alternatively, the pad is preferably used for mounting a surface mount package component. Still alternatively, the pad is preferably used for mounting an electronic component provided with terminals around its end surface. Still further alternatively, the printed circuit board preferably includes the plurality of mounting sections including at least two kinds of mounting sections one by one used for mounting a flexible printed circuit board, a surface mount package component and an electronic component provided with terminals around its end surface.

In any configuration of the first aspect of the present invention, the second solder resist is preferably deposited in several batches.

To achieve the above object, the second aspect of the present invention provides a method of producing a printed circuit board including a plurality of pads used for surface mounting, including: forming a first solder resist on the surface of the printed circuit board so as to expose the pads, forming a second solder resist between the adjacent pads, and providing a printing layer of solder paste which is as high as or higher than the second solder resist by printing on the pad separated from other pads by the first and the second solder resists.

In the second aspect of the present invention, the second solder resist is preferably deposited in several batches.

### BRIEF DESCRIPTION OF THE DRAWINGS

The objects and features of the present invention will become more apparent from the consideration of the following detailed description taken in conjunction with the accompanying drawings, in which:

FIG. 1 is a view illustrating a configuration of a portion where an FPC is mounted on a PCB according to a first embodiment that preferably carries out the present invention;

FIG. 2 is a cross section of the portion where the FPC is connected to the PCB;

FIG. 3 is a view illustrating a configuration of a portion where a package component is mounted on a PCB according to a second embodiment that preferably carries out the present invention; and

FIG. 4 is a view illustrating a configuration of a portion where electronic components are mounted on a PCB according to a third embodiment that preferably carries out the present invention.

### EXEMPLARY EMBODIMENT

### First Exemplary Embodiment

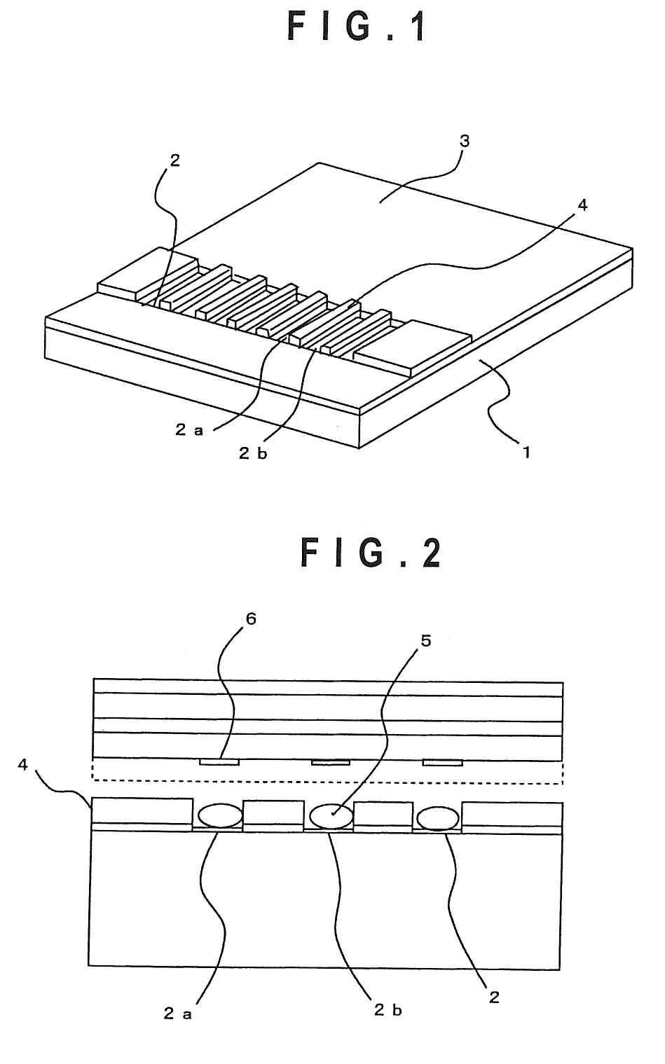

A first exemplary embodiment that preferably carries out the present invention is described below. FIG. 1 illustrates a configuration of a PCB according to the present embodiment. The PCB is configured such that pads 2 are formed on a substrate 1 and a first solder resist 3 is formed except where the pads 2 are formed. Furthermore, a second solder resist 4 is formed between the adjacent pads (for example, between pads 2a and 2b).

The steps for mounting the FPC on the PCB are described below. FIG. 2 illustrates a cross section of a portion where the FPC is connected to the PCB.

A solder 5 is printed on the pad 2 on the PCB. An FPC pad 6 is located at a position where respective pads are connected to each other. After that, the solder 5 is melted by the reflow method. At this point, even if a molten solder 5 is about to flow into the adjacent pad 2b, the molten solder 5 is dammed by the second solder resist 4 to remain on the pad 2a.

Automatically mounting the FPC by the reflow method enables the FPC to be mounted along with other electronic components to reduce man-hour for production. In addition, solder defects after reflow can be avoided, which improves yield.

Narrow-pitch mounting is enabled to meet the requirement for downsizing and compacting a product.

Thus, depositing the solder resist several times between the surface mount pads of the PCB connected to the FPC enables molten solder to be dammed. This allows the PCB to be soldered to the FPC by a general reflow soldering process, which does not require using dedicated facilities to solder the FPC to the PCB.

Furthermore, the convex portion of the pad of the FPC can be fitted into the concave portion on the PCB formed by depositing the solder resist several times, which facilitates positioning therebetween.

### Second Exemplary Embodiment

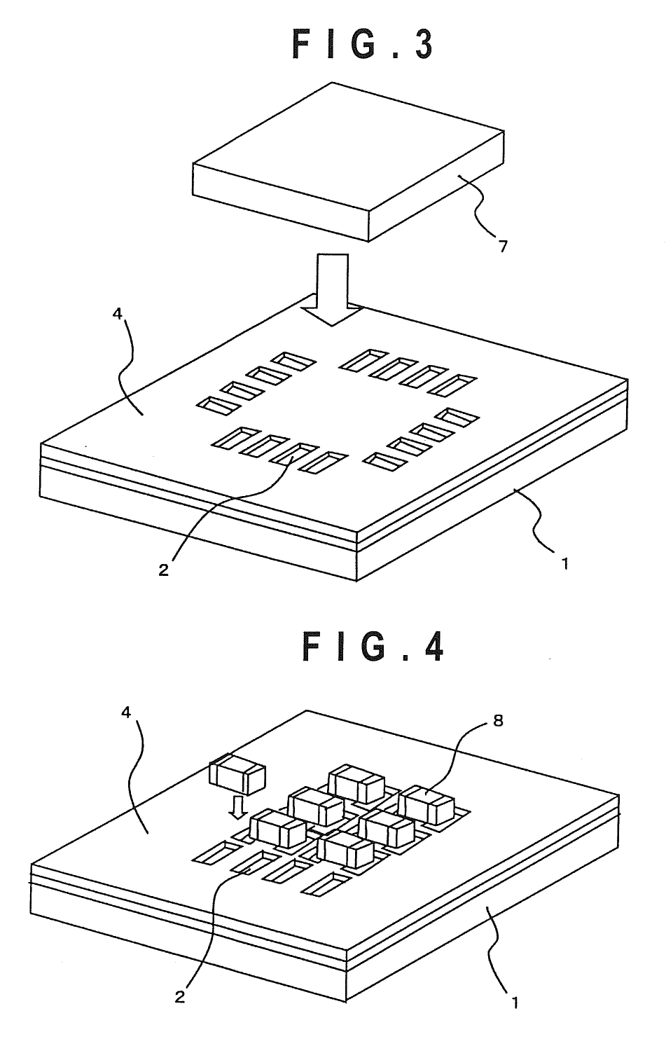

A second exemplary embodiment that preferably carries out the present invention is described below. FIG. 3 illustrates a configuration of a PCB according to the present embodiment. For pads on which surface mount package components such as LGA or QFN are mounted, as is the case with the first embodiment, depositing the solder resist several times enables molten solder to be prevented from flowing into the adjacent pads, which allows narrow-pitch mounting to meet the requirement for downsizing and compacting a product. In this case, also, the convex portion of the pad of the package component can be fitted into the concave portion on the PCB formed by depositing the solder resist several times, which facilitates positioning therebetween.

### Third Exemplary Embodiment

A third exemplary embodiment that preferably carries out the present invention is described below. FIG. 4 illustrates a configuration of a PCB according to the present embodiment. For pads on which surface mount electronic components are mounted, as is the case with the first embodiment, depositing the solder resist several times enables molten solder to be prevented from flowing into the adjacent pads, which allows narrow-pitch mounting to meet the requirement for downsizing and compacting a product. In this case, also, the convex portion of the pad of the electronic component can be fitted into the concave portion on the PCB formed by depositing the solder resist several times, which facilitates positioning therebetween.

Although the above embodiments take an example where any of the FPC, the package component and the electronic component is mounted on the PCB, the present invention may be applicable to the case where the FPC, the package component and the electronic component are combined to be mounted on the PCB, which enables molten solder to be prevented from flowing into the adjacent pads, allowing narrow-pitch mounting to realize downsizing and compacting a product.

According to the present invention, there can be provided a printed circuit board in which space between pads used for surface mounting can be narrowed and an FPC can be mounted along with electronic components by the reflow method even when the FPC is mounted and a method of producing the same.

Incidentally, the above embodiments are one example of preferable embodiments of the present invention, and the present invention is not limited to these embodiments.

For example, although the solder resist is deposited twice in the embodiments, the solder resist may be deposited three times or more. Changing the number of depositions of the solder resist enables the height of the wall to be changed according to the quantity of solder.

Thus, the present invention enables various modifications.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A printed circuit board provided with a mounting section comprising a plurality of pads used for surface mounting, wherein
a first solder resist is formed on a surface of the printed circuit board so as to expose the pads,
a second solder resist is formed between the adjacent pads, and
a printing layer of solder paste which is as high as or higher than the second solder resist is provided on the pad separated from other pads by the first and the second solder resists.

2. The printed circuit board according to claim 1, wherein
the pad is used for mounting a flexible printed circuit board.

3. The printed circuit board according to claim 1, wherein
the pad is used for mounting a surface mount package component.

4. The printed circuit board according to claim 1, wherein
the pad is used for mounting an electronic component provided with terminals around its end surface.

5. The printed circuit board according to claim 1, comprising the plurality of mounting sections including at least two kinds of mounting sections one by one for mounting a flexible printed circuit board, a surface mount package component and an electronic component provided with terminals around its end surface.

6. The printed circuit board according to claim 1, wherein
the second solder resist is deposited in several batches.

7. A method of producing a printed circuit board comprising a plurality of pads used for surface mounting, comprising:
forming a first solder resist on a surface of the printed circuit board so as to expose the pads,
forming a second solder resist between the adjacent pads, and
providing a printing layer of solder paste which is as high as or higher than the second solder resist by printing on the pad separated from other pads by the first and the second solder resists.

8. The method of producing a printed circuit board according to claim 7, wherein,
the second solder resist is deposited in several batches.
